(19) United States
(12) Patent Application Publication
(10) Pub. No.: US 2026/0227710 A1
(43) Pub. Date: Aug. 6, 2026

(54) RETICLE FRONTSIDE POTENTIAL CONTROL WITH CLAMP BURL CONNECTION

(71) Applicant: ASML NETHERLANDS B.V., Veldhoven (NL)

(72) Inventors: Hari KRISHNAN, Norwalk, CT (US); Ankur Ramesh BAHETI, Wilton, CT (US)

(73) Assignee: ASML NETHERLANDS B.V., Veldhoven (NL)

(21) Appl. No.: 19/149,816

(22) PCT Filed: Jan. 16, 2024
(86) PCT No.: PCT/EP2024/050892

§ 371 Date: Jul. 21, 2025

Related U.S. Application Data
(60) Provisional application No. 63/445,262, filed on Feb. 13, 2023.

(51) Int. Cl. G03F 7/00

(52) U.S. Cl. CPC G03F 7/70708; G03F 7/70033

(57) ABSTRACT

An electrostatic reticle clamp includes a dielectric body, electrodes configured to apply a charge to a first side of the body for electrostatically clamping a reticle on a second side of the dielectric body, a plurality of burls on the second side of the dielectric body and configured to contact the reticle, a conductive coating disposed on a surface of a subset of the burls, a power source, and a controller configured to provide voltage from the power source to the conductive coating.

### CROSS-REFERENCE TO RELATED APPLICATION

This application claims priority of U.S. application 63/445,262 which was filed on 13 Feb. 2023 and which is incorporated herein in its entirety by reference.

### FIELD OF THE INVENTION

The present invention relates to systems and methods for reducing particle formation on reticles.

### BACKGROUND OF THE INVENTION

During various types of lithography, particle formation can create significant defects and result in yield loss. Defectivity is often measured as added particles per reticle pass (PRP), which is typically measured as the added particles on a reticle per 10000 wafers.

For example, in EUV lithography, during EUV pulses, the EUV beam exposes the reticle. In effect there are two sources of electrons released in the reticle mini environment (RME): 1) from the photo-electric effect (expelled from reticle) and 2) electrons from photo-ionizations in the volume. Because electrons are released from the reticle, the reticle frontside gets a positive charge (not all electrons return to reticle). The cumulative effect of all the electrons along with the EUV plasma result in negatively charged particles in the RME, which then get attracted to the positively charged reticle frontside causing an increase in PRP.

There is a continuing need to reduce PRP to improve yield.

### SUMMARY

The present invention provides the ability to control the potential on the reticle backside and hence the reticle frontside of a clamped reticle using the electrostatic reticle clamp. By controlling potential on the reticle frontside, PRP can be reduced.

In an embodiment, an electrostatic reticle clamp includes a dielectric body, electrodes configured to apply a charge to a first side of the body for electrostatically clamping a reticle on a second side of the dielectric body, a plurality of burls on the second side of the dielectric body and configured to contact the reticle, a conductive coating disposed on a surface of a subset of the burls, a power source, and a controller configured to provide voltage from the power source to the conductive coating.

In an embodiment, the controller and power source are configured to apply a positive voltage to the conductive coating which applies a positive potential to the backside of a reticle mounted on the burls for reducing the amount of electrons that are released into a reticle mini environment during an EUV pulse.

In an embodiment, the controller and power source are configured to apply a positive voltage to the conductive coating to apply a positive charge to a frontside of the reticle. In an embodiment, the controller and power source are configured to apply a negative voltage to the conductive coating to apply a negative charge to a backside of a reticle mounted on the burls for repelling particles from a frontside of the reticle between EUV pulses.

In an embodiment, the controller and power source are configured to apply a negative voltage to the conductive coating to apply a negative charge to a frontside of the reticle. In an embodiment, the conductive coating comprises a chrome (Cr) or titanium nitride (TiN) coating.

In an embodiment, the electrostatic reticle clamp further comprises a plurality of high voltage and ground connections on ear portions of the clamp, wherein the ear portions are coated with a conductive clamp ear coating, and wherein the conductive clamp ear coating is connected to the ground pin on at least one of the clamp ear portions. In an embodiment, the electrostatic reticle clamp further comprises one or more caps disposed over the ear portions, wherein the one or more caps are electrically connected with the conductive clamp ear coating.

In an embodiment, the conductive coating crosses over a raised structure separating the clamp ear portions and the burls, wherein the raised structure comprises a leaky seal for connecting the burls. In an embodiment, the ground connection on one of the ears is modified to provide voltage to the conductive coating, and wherein the ground pin on the other ear remains connected to ground. In an embodiment, the at least one electrode is connected to ground. In an embodiment, the conductive coating provides a conductive path from the power source to the surface on the subset of burls.

In an embodiment, a method for forming an electrostatic reticle clamp includes providing a dielectric body with a plurality of burls on a first side thereof, applying a conductive coating to the first side of the dielectric body, and patterning the conductive coating on the first side of the body by retaining the coating on a subset of the burls and a conductive path to enable a potential to be applied to the subset of burls through the conductive path.

In an embodiment, the patterning comprises a lithographic patterning process to provide a conductive path to the subset of burls from at least one clamp ear at a peripheral portion of the clamp. In an embodiment, the method further provides at least one glass body on a second side of the dielectric body, and two electrodes between the dielectric body and the at least one glass body.

### BRIEF DESCRIPTION OF THE DRAWINGS

FIG. 1 schematically depicts a lithography apparatus, according to an embodiment.

FIG. 2 schematically depicts an embodiment of a lithographic cell or cluster, according to an embodiment.

FIG. 3 is a schematic diagram of a lithographic projection apparatus similar to FIG. 1, according to an embodiment.

FIG. 4 schematically depicts a more detailed view of the lithographic projection apparatus.

FIG. 5 schematically depicts a reticle clamp.

FIG. 6 schematically depicts a cross-sectional view of an exploded reticle clamp.

FIG. 7 schematically depicts a clamping function of the reticle clamp.

FIG. 8 schematically depicts a charged particle effect and biasing of the reticle when an exposure beam is on.

FIG. 9 schematically depicts the charged particle effect and biasing of the reticle when the exposure beam is on.

FIG. 10 schematically depicts the charged particle effect and biasing of the reticle when the exposure beam is off.

FIG. 11 schematically depicts an embodiment of an electrostatic reticle clamp.

FIG. 12 schematically depicts an embodiment to achieve reticle frontside potential.

FIGS. 13A-13B schematically depict an embodiment to enable burl potential control.

FIGS. 14A-14B schematically depict an embodiment to enable burl potential control and true ground.

FIG. 15 schematically depicts an embodiment of the burl configuration.

### DETAILED DESCRIPTION

In general, a mask or reticle may be a transparent block of material that is covered with a pattern defined by a different, opaque material. Various masks are fed into a lithographic apparatus and used to form layers of a semiconductor device. The pattern defined on a given mask or reticle corresponds to features produced in one or more layers of the semiconductor device. Often, a plurality of masks or reticles are automatically fed into a lithographic apparatus during manufacturing and used to form corresponding layers of a semiconductor device. A clamp (e.g., an electrostatic reticle clamp) in the lithographic apparatus is used to secure a masks or reticles during processing. This clamp may become contaminated with particles of material transferred from reticles causing performance degradation over time, and requiring periodic cleaning to restore performance.

Cleaning these clamps can require stopping the lithographic apparatus and the manufacturing process. This cleaning can require several hours to complete, expose the environment inside the lithographic apparatus to ambient conditions, may introduce other contaminants into the system, and/or have other disadvantages. In addition, there is a flushing process where extremely clean dry air (XCDA) is cycled through the chamber to remove the particles, but this too requires multiple hours and is not completely effective in cleaning these particles since particles still end up on the frontside of the reticle impacting PRP performance.

In contrast to prior approaches, the present systems and methods provide a system where particles are repelled from the reticle frontside and hence do not adhere to the reticle frontside. In the present systems and methods, a grounded pin in a electrostatic reticle clamp is repurposed to function as a reticle frontside potential connection. A strip of conductive coating (e.g., Cr, TiN) can be routed from an ear section of the clamp to a small portion of burls on the clamp. This connection can drive a slightly positive voltage, 5-10V, for example. The reticle can include a conductive coating electrically connecting the backside of the clamp to the frontside. When the backside of the reticle contacts the electrically connected clamp burls, voltage can be supplied from the grounding pins, through the conductive coating on the clamp, to the conductive coating on the reticle. The frontside of the reticle then has a positive charge and can repel particles.

Although specific reference may be made in this text to the manufacture of integrated circuits (ICs), it should be understood that the description herein has many other possible applications. For example, it may be employed in the manufacture of integrated optical systems, guidance and detection patterns for magnetic domain memories, liquid-crystal display panels, thin-film magnetic heads, etc. The skilled artisan will appreciate that, in the context of such alternative applications, any use of the terms “reticle”, “wafer” or “die” in this text should be considered as interchangeable with the more general terms “mask”, “substrate” and “target portion”, respectively. In addition, any use of the terms “reticle” or “mask” herein may be considered synonymous with the more general term “patterning device.”

As an introduction, prior to transferring a pattern from a reticle such as a mask to a substrate, the substrate may undergo various procedures, such as priming, resist coating and a soft bake. After exposure, the substrate may be subjected to other procedures (“post-exposure procedures”), such as a post-exposure bake (PEB), development, a hard bake and measurement and/or other inspection of the transferred pattern. This array of procedures is used as a basis to make an individual layer of a device, e.g., an IC. The substrate may then undergo various processes such as etching, ion-implantation (doping), metallization, oxidation, chemical mechanical polishing, etc., all intended to finish an individual layer of the device. If several layers are required in the device, then the whole procedure, or a variant thereof, is repeated for each layer. Eventually, a device will be present in each target portion on the substrate. These devices are then separated from one another by a technique such as dicing or sawing, whence the individual devices can be mounted on a carrier, connected to pins, etc.

Manufacturing devices, such as semiconductor devices, typically involves processing a substrate (e.g., a semiconductor wafer) using a number of fabrication processes to form various features and multiple layers of the devices. Such layers and features are typically manufactured and processed using, e.g., deposition, lithography, etch, chemical mechanical polishing, ion implantation, and/or other processes. Multiple devices may be fabricated on a plurality of dies on a substrate and then separated into individual devices. This device manufacturing process may be considered a patterning process. A patterning process involves a patterning step, such as optical and/or nanoimprint lithography using a reticle in a lithographic apparatus, to transfer a pattern on the reticle to a substrate and typically, but optionally, involves one or more related pattern processing steps, such as resist development by a development apparatus, baking of the substrate using a bake tool, etching using the pattern using an etch apparatus, etc. One or more metrology processes are typically involved in the patterning process.

Lithography is a step in the manufacturing of device such as ICs, where patterns formed on substrates define functional elements of the devices, such as microprocessors, memory chips, etc.

Similar lithographic techniques are also used in the formation of flat panel displays, micro-electromechanical systems (MEMS) and other devices.

As semiconductor manufacturing processes continue to advance, the dimensions of functional elements have continually been reduced while the number of functional elements, such as transistors, per device has been steadily increasing over decades, following a trend commonly referred to as “Moore's law”. At the current state of technology, layers of devices are manufactured using lithographic projection apparatuses that project a design layout onto a substrate using illumination from a deep-ultraviolet illumination source, creating individual functional elements having dimensions well below 100 nm, i.e. less than half the wavelength of the radiation from the illumination source (e.g., a 193 nm illumination source).

This process in which features with dimensions smaller than the classical resolution limit of a lithographic projection apparatus are printed, is commonly known as low-k1 lithography, according to the resolution formula CD=k1×λ/NA, where λ is the wavelength of radiation employed (currently in most cases 248 nm or 193 nm), NA is the numerical aperture of projection optics in the lithographic projection apparatus, CD is the “critical dimension”—generally the smallest feature size printed—and k1 is an empirical resolution factor. In general, the smaller k1 the more difficult it becomes to reproduce a pattern on the substrate that resembles the shape and dimensions planned by a designer in order to achieve particular electrical functionality and performance. To overcome these difficulties, sophisticated fine-tuning steps are applied to the lithographic projection apparatus, the design layout, or the reticle. These include, for example, but not limited to, optimization of NA and optical coherence settings, customized illumination schemes, use of phase shifting reticles, optical proximity correction (OPC, sometimes also referred to as “optical and process correction”) in the design layout, overlay measurement, or other methods generally defined as “resolution enhancement techniques” (RET).

The term “projection optics” as used herein should be broadly interpreted as encompassing various types of optical systems, including refractive optics, reflective optics, apertures and catadioptric optics, for example. The term “projection optics” may also include components operating according to any of these design types for directing, shaping, or controlling the projection beam of radiation, collectively or singularly. The term “projection optics” may include any optical component in the lithographic projection apparatus, no matter where the optical component is located on an optical path of the lithographic projection apparatus. Projection optics may include optical components for shaping, adjusting and/or projecting radiation from the source before the radiation passes the reticle, and/or optical components for shaping, adjusting and/or projecting the radiation after the radiation passes the reticle. The projection optics generally exclude the source and the reticle.

FIG. 1 schematically depicts an embodiment of a lithographic apparatus LA that may be included in and/or associated with the present systems and/or methods. The apparatus comprises: an illumination system (illuminator) IL configured to condition a radiation beam B (e.g., UV radiation, DUV radiation, or EUV radiation); a support structure (e.g., a mask table) MT constructed to support a reticle (e.g., a mask) MA and connected to a first positioner PM configured to accurately position the reticle in accordance with certain parameters; a substrate table (e.g., a wafer table) WT (e.g., WTa, WTb or both) configured to hold a substrate (e.g., a resist-coated wafer) W and coupled to a second positioner PW configured to accurately position the substrate in accordance with certain parameters; and a projection system (e.g., a refractive projection lens system) PS configured to project a pattern imparted to the radiation beam B by reticle MA onto a target portion C (e.g., comprising one or more dies and often referred to as fields) of the substrate W. The projection system is supported on a reference frame (RF). As depicted, the apparatus is of a transmissive type (e.g., employing a transmissive mask). Alternatively, the apparatus may be of a reflective type (e.g., employing a programmable mirror array of a type as referred to above, or employing a reflective mask).

The illuminator IL receives a beam of radiation from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD comprising for example suitable directing mirrors and/or a beam expander. In other cases, the source may be an integral part of the apparatus, for example when the source is a mercury lamp. The source SO and the illuminator IL, together with the beam delivery system BD if required, may be referred to as a radiation system.

The illuminator IL may alter the intensity distribution of the beam. The illuminator may be arranged to limit the radial extent of the radiation beam such that the intensity distribution is non-zero within an annular region in a pupil plane of the illuminator IL. Additionally, or alternatively, the illuminator IL may be operable to limit the distribution of the beam in the pupil plane such that the intensity distribution is non-zero in a plurality of equally spaced sectors in the pupil plane. The intensity distribution of the radiation beam in a pupil plane of the illuminator IL may be referred to as an illumination mode.

The illuminator IL may comprise adjuster AD configured to adjust the (angular/spatial) intensity distribution of the beam. Generally, at least the outer and/or inner radial extent (commonly referred to as o-outer and o-inner, respectively) of the intensity distribution in a pupil plane of the illuminator can be adjusted. The illuminator IL may be operable to vary the angular distribution of the beam. For example, the illuminator may be operable to alter the number, and angular extent, of sectors in the pupil plane wherein the intensity distribution is non-zero. By adjusting the intensity distribution of the beam in the pupil plane of the illuminator, different illumination modes may be achieved. For example, by limiting the radial and angular extent of the intensity distribution in the pupil plane of the illuminator IL, the intensity distribution may have a multi-pole distribution such as, for example, a dipole, quadrupole or hexapole distribution. A desired illumination mode may be obtained, e.g., by inserting an optic which provides that illumination mode into the illuminator IL or using a spatial light modulator.

The illuminator IL may be operable to alter the polarization of the beam and may be operable to adjust the polarization using adjuster AD. The polarization state of the radiation beam across a pupil plane of the illuminator IL may be referred to as a polarization mode. The use of different polarization modes may allow greater contrast to be achieved in the image formed on the substrate W. The radiation beam may be unpolarized. Alternatively, the illuminator may be arranged to linearly polarize the radiation beam. The polarization direction of the radiation beam may vary across a pupil plane of the illuminator IL. The polarization direction of radiation may be different in different regions in the pupil plane of the illuminator IL. The polarization state of the radiation may be chosen in dependence on the illumination mode. For multi-pole illumination modes, the polarization of each pole of the radiation beam may be generally perpendicular to the position vector of that pole in the pupil plane of the illuminator IL. For example, for a dipole illumination mode, the radiation may be linearly polarized in a direction that is substantially perpendicular to a line that bisects the two opposing sectors of the dipole. The radiation beam may be polarized in one of two different orthogonal directions, which may be referred to as X-polarized and Y-polarized states. For a quadrupole illumination mode, the radiation in the sector of each pole may be linearly polarized in a direction that is substantially perpendicular to a line that bisects that sector. This polarization mode may be referred to as XY polarization. Similarly, for a hexapole illumination mode the radiation in the sector of each pole may be linearly polarized in a direction that is substantially perpendicular to a line that bisects that sector. This polarization mode may be referred to as TE polarization.

In addition, the illuminator IL generally comprises various other components, such as an integrator IN and a condenser CO. The illumination system may include various types of optical components, such as refractive, reflective, magnetic, electromagnetic, electrostatic, or other types of optical components, or any combination thereof, for directing, shaping, or controlling radiation. Thus, the illuminator provides a conditioned beam of radiation B, having a desired uniformity and intensity distribution in its cross section.

The support structure MT supports the reticle in a manner that depends on the orientation of the reticle, the design of the lithographic apparatus, and other conditions, such as for example whether or not the reticle is held in a vacuum environment. The support structure may use mechanical, vacuum, electrostatic or other clamping techniques to hold the reticle. The support structure may be a frame or a table, for example, which may be fixed or movable as required. The support structure may ensure that the reticle is at a desired position, for example with respect to the projection system.

The term “reticle” used herein should be broadly interpreted as referring to any device that can be used to impart a pattern in a target portion of the substrate. In an embodiment, a reticle is any device that can be used to impart a radiation beam with a pattern in its cross-section to create a pattern in a target portion of the substrate. It should be noted that the pattern imparted to the radiation beam may not exactly correspond to the desired pattern in the target portion of the substrate, for example if the pattern includes phase-shifting features or so-called assist features. Generally, the pattern imparted to the radiation beam will correspond to a particular functional layer in a device being created in a target portion of the device, such as an integrated circuit.

A patterning device may be transmissive or reflective. Examples of patterning devices include reticles or masks, programmable mirror arrays, and programmable LCD panels. Reticles or masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted to reflect an incoming radiation beam in different directions. The tilted mirrors impart a pattern in a radiation beam, which is reflected by the mirror matrix.

The term “projection system” used herein should be broadly interpreted as encompassing any type of projection system, including refractive, reflective, catadioptric, magnetic, electromagnetic, and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system”.

The projection system PS has an optical transfer function which may be non-uniform, which can affect the pattern imaged on the substrate W. For unpolarized radiation such effects can be fairly well described by two scalar maps, which describe the transmission (apodization) and relative phase (aberration) of radiation exiting the projection system PS as a function of position in a pupil plane thereof. These scalar maps, which may be referred to as the transmission map and the relative phase map, may be expressed as a linear combination of a complete set of Basis functions. A convenient set is the Zernike polynomials, which form a set of orthogonal polynomials defined on a unit circle. A determination of each scalar map may involve determining the coefficients in such an expansion. Since the Zernike polynomials are orthogonal on the unit circle, the Zernike coefficients may be determined by calculating the inner product of a measured scalar map with each Zernike polynomial in turn and dividing this by the square of the norm of that Zernike polynomial.

The transmission map and the relative phase map are field and system dependent. That is, in general, each projection system PS will have a different Zernike expansion for each field point (i.e. for each spatial location in its image plane). The relative phase of the projection system PS in its pupil plane may be determined by projecting radiation, for example from a point-like source in an object plane of the projection system PS (i.e., the plane of the reticle MA), through the projection system PS and using a shearing interferometer to measure a wavefront (i.e., a locus of points with the same phase). A shearing interferometer is a common path interferometer and therefore, advantageously, no secondary reference beam is required to measure the wavefront. The shearing interferometer may comprise a diffraction grating, for example a two-dimensional grid, in an image plane of the projection system (i.e. the substrate table WTa or WTb) and a detector arranged to detect an interference pattern in a plane that is conjugate to a pupil plane of the projection system PS. The interference pattern is related to the derivative of the phase of the radiation with respect to a coordinate in the pupil plane in the shearing direction. The detector may comprise an array of sensing elements such as, for example, charge coupled devices (CCDs).

The projection system PS of a lithography apparatus may not produce visible fringes and therefore the accuracy of the determination of the wavefront can be enhanced using phase stepping techniques such as, for example, moving the diffraction grating. Stepping may be performed in the plane of the diffraction grating and in a direction perpendicular to the scanning direction of the measurement. The stepping range may be one grating period, and at least three (uniformly distributed) phase steps may be used. Thus, for example, three scanning measurements may be performed in the y-direction, each scanning measurement being performed for a different position in the x-direction. This stepping of the diffraction grating effectively transforms phase variations into intensity variations, allowing phase information to be determined. The grating may be stepped in a direction perpendicular to the diffraction grating (z direction) to calibrate the detector.

The diffraction grating may be sequentially scanned in two perpendicular directions, which may coincide with axes of a co-ordinate system of the projection system PS (x and y) or may be at an angle such as 45 degrees to these axes. Scanning may be performed over an integer number of grating periods, for example one grating period. The scanning averages out phase variation in one direction, allowing phase variation in the other direction to be reconstructed. This allows the wavefront to be determined as a function of both directions.

The transmission (apodization) of the projection system PS in its pupil plane may be determined by projecting radiation, for example from a point-like source in an object plane of the projection system PS (i.e., the plane of the reticle MA), through the projection system PS and measuring the intensity of radiation in a plane that is conjugate to a pupil plane of the projection system PS, using a detector. The same detector as is used to measure the wavefront to determine aberrations may be used.

The projection system PS may comprise a plurality of optical (e.g., lens) elements and may further comprise an adjustment mechanism configured to adjust one or more of the optical elements to correct for aberrations (phase variations across the pupil plane throughout the field). To achieve this, the adjustment mechanism may be operable to manipulate one or more optical (e.g., lens) elements within the projection system PS in one or more different ways. The projection system may have a co-ordinate system wherein its optical axis extends in the z direction. The adjustment mechanism may be operable to do any combination of the following: displace one or more optical elements; tilt one or more optical elements; and/or deform one or more optical elements. Displacement of an optical element may be in any direction (x, y, z, or a combination thereof). Tilting of an optical element is typically out of a plane perpendicular to the optical axis, by rotating about an axis in the x and/or y directions although a rotation about the z axis may be used for a non-rotationally symmetric aspherical optical element. Deformation of an optical element may include a low frequency shape (e.g., astigmatic) and/or a high frequency shape (e.g., free form aspheres). Deformation of an optical element may be performed for example by using one or more actuators to exert force on one or more sides of the optical element and/or by using one or more heating elements to heat one or more selected regions of the optical element. In general, it may not be possible to adjust the projection system PS to correct for apodization (transmission variation across the pupil plane). The transmission map of a projection system PS may be used when designing a reticle (e.g., mask) MA for the lithography apparatus LA. Using a computational lithography technique, the reticle MA may be designed to correct for apodization at least partially.

The lithographic apparatus may be of a type having two (dual stage) or more tables (e.g., two or more substrate tables WTa, WTb, two or more reticle tables, a substrate table WTa and a table WTb below the projection system without a substrate that is dedicated to, for example, facilitating measurement, and/or cleaning, etc.). In such “multiple stage” machines, the additional tables may be used in parallel, or preparatory steps may be carried out on one or more tables while one or more other tables are being used for exposure. For example, alignment measurements using an alignment sensor AS and/or level (height, tilt, etc.) measurements using a level sensor LS may be made.

The lithographic apparatus may also be of a type wherein at least a portion of the substrate may be covered by a liquid having a relatively high refractive index, e.g., water, to fill a space between the projection system and the substrate. An immersion liquid may also be applied to other spaces in the lithographic apparatus, for example, between the reticle and the projection system.

Immersion techniques are well known in the art for increasing the numerical aperture of projection systems. The term “immersion” as used herein does not mean that a structure, such as a substrate, must be submerged in liquid, but rather only means that liquid is located between the projection system and the substrate during exposure.

In operation of the lithographic apparatus, a radiation beam is conditioned and provided by the illumination system IL. The radiation beam B is incident on the reticle (e.g., mask) MA, which is held on the support structure (e.g., mask table) MT. Having traversed the reticle MA, the radiation beam B passes through the projection system PS, which focuses the beam onto a target portion C of the substrate W. With the aid of the second positioner PW and position sensor IF (e.g., an interferometric device, linear encoder, 2-D encoder, or capacitive sensor), the substrate table WT can be moved accurately, e.g., to position different target portions C in the path of the radiation beam B. Similarly, the first positioner PM and another position sensor (which is not explicitly depicted in FIG. 1) can be used to accurately position the reticle MA with respect to the path of the radiation beam B, e.g., after mechanical retrieval from a mask library, or during a scan. In general, movement of the support structure MT may be realized with the aid of a long-stroke module (coarse positioning) and a short-stroke module (fine positioning), which form part of the first positioner PM. Similarly, movement of the substrate table WT may be realized using a long-stroke module and a short-stroke module, which form part of the second positioner PW. In the case of a stepper (as opposed to a scanner), the support structure MT may be connected to a short-stroke actuator only or may be fixed. reticle MA and substrate W may be aligned using reticle alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the reticle MA, the reticle alignment marks may be located between the dies.

The depicted apparatus may be used in at least one of the following modes: 1. In step mode, the support structure MT and the substrate table WT are kept essentially stationary, while a pattern imparted to the radiation beam is projected onto a target portion C at one time (i.e., a single static exposure). The substrate table WT is then shifted in the X and/or Y direction so that a different target portion C can be exposed. In step mode, the maximum size of the exposure field limits the size of the target portion C imaged in a single static exposure. 2. In scan mode, the support structure MT and the substrate table WT are scanned synchronously while a pattern imparted to the radiation beam is projected onto a target portion C (i.e., a single dynamic exposure). The velocity and direction of the substrate table WT relative to the support structure MT may be determined by the (de-) magnification and image reversal characteristics of the projection system PS. In scan mode, the maximum size of the exposure field limits the width (in the non-scanning direction) of the target portion in a single dynamic exposure, whereas the length of the scanning motion determines the height (in the scanning direction) of the target portion. 3. In another mode, the support structure MT is kept essentially stationary holding a programmable reticle, and the substrate table WT is moved or scanned while a pattern imparted to the radiation beam is projected onto a target portion C. In this mode, generally a pulsed radiation source is employed, and the programmable reticle is updated as required after each movement of the substrate table WT or in between successive radiation pulses during a scan. This mode of operation can be readily applied to maskless lithography that utilizes programmable reticle, such as a programmable mirror array of a type as referred to above. Combinations and/or variations on the above-described modes of use or entirely different modes of use may also be employed.

A substrate may be processed, before or after exposure, in for example a track (a tool that typically applies a layer of resist to a substrate and develops the exposed resist) or a metrology or inspection tool. Where applicable, the disclosure herein may be applied to such and other substrate processing tools. Further, the substrate may be processed more than once, for example in order to create a multi-layer IC, so that the term substrate used herein may also refer to a substrate that already includes multiple processed layers.

The terms “radiation” and “beam” used herein encompass all types of electromagnetic radiation, including ultraviolet (UV) or deep ultraviolet (DUV) radiation (e.g., having a wavelength of 365, 248, 193, 157 or 126 nm) and extreme ultra-violet (EUV) radiation (e.g., having a wavelength in the range of 5-20 nm), as well as particle beams, such as ion beams or electron beams.

Various patterns on or provided by a reticle may have different process windows. i.e., a space of processing variables under which a pattern will be produced within specification. Examples of pattern specifications that relate to potential systematic defects include checks for necking, line pull back, line thinning, critical dimension (CD), edge placement, overlapping, resist top loss, resist undercut and/or bridging. The process window of the patterns on a reticle or an area thereof may be obtained by merging (e.g., overlapping) process windows of each individual pattern. The boundary of the process window of a group of patterns comprises boundaries of process windows of some of the individual patterns. In other words, these individual patterns limit the process window of the group of patterns. These patterns can be referred to as “hot spots” or “process window limiting patterns (PWLPs),” which are used interchangeably herein. When controlling a part of a patterning process, it is possible and economical to focus on the hot spots. When the hot spots are not defective, it is most likely that other patterns are not defective.

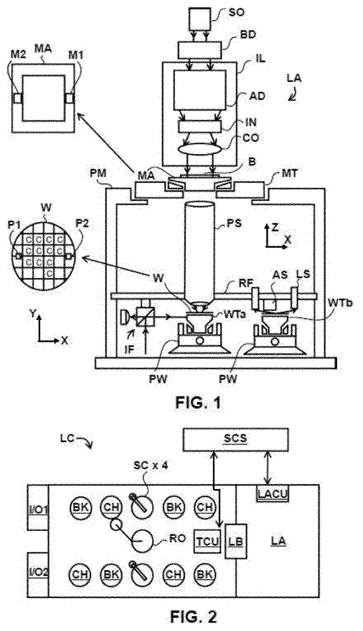

As shown in FIG. 2, the lithographic apparatus LA may form part of a lithographic cell LC, also sometimes referred to a lithocell or cluster, which also includes apparatuses to perform pre-and post-exposure processes on a substrate. Conventionally these include one or more spin coaters SC to deposit one or more resist layers, one or more developers to develop exposed resist, one or more chill plates CH and/or one or more bake plates BK. A substrate handler, or robot, RO picks up one or more substrates from input/output port I/O1, I/O2, moves them between the different process apparatuses and delivers them to the loading bay LB of the lithographic apparatus. These apparatuses, which are often collectively referred to as the track, are under the control of a track control unit TCU which is itself controlled by the supervisory control system SCS, which also controls the lithographic apparatus via lithography control unit LACU. Thus, the different apparatuses can be operated to maximize throughput and processing efficiency.

In order that a substrate that is exposed by the lithographic apparatus is exposed correctly and consistently and/or in order to monitor a part of the patterning process (e.g., a device manufacturing process) that includes at least one pattern transfer step (e.g., an optical lithography step), it is desirable to inspect a substrate or other object to measure or determine one or more properties such as alignment, overlay (which can be, for example, between structures in overlying layers or between structures in a same layer that have been provided separately to the layer by, for example, a double patterning process), line thickness, critical dimension (CD), focus offset, a material property, etc. For example, contamination on reticle clamp membranes (e.g., as described herein) may adversely affect overlay because clamping a reticle over such contamination will distort the reticle. Accordingly, a manufacturing facility in which lithocell LC is located also typically includes a metrology system that measures some or all of the substrates W (FIG. 1) that have been processed in the lithocell or other objects in the lithocell. The metrology system may be part of the lithocell LC, for example it may be part of the lithographic apparatus LA (such as alignment sensor AS (FIG. 1)).

The one or more measured parameters may include, for example, alignment, overlay between successive layers formed in or on the patterned substrate, critical dimension (CD) (e.g., critical linewidth) of, for example, features formed in or on the patterned substrate, focus or focus error of an optical lithography step, dose or dose error of an optical lithography step, optical aberrations of an optical lithography step, etc. This measurement may be performed on a target of the product substrate itself and/or on a dedicated metrology target provided on the substrate. The measurement can be performed after-development of a resist but before etching, after-etching, after deposition, and/or at other times.

There are various techniques for making measurements of the structures formed in the patterning process, including the use of a scanning electron microscope, an image-based measurement tool and/or various specialized tools. As discussed above, a fast and non-invasive form of specialized metrology tool is one in which a beam of radiation is directed onto a target on the surface of the substrate and properties of the scattered (diffracted/reflected) beam are measured. By evaluating one or more properties of the radiation scattered by the substrate, one or more properties of the substrate can be determined. This may be termed diffraction-based metrology. One such application of this diffraction-based metrology is in the measurement of feature asymmetry within a target. This can be used as a measure of overlay, for example, but other applications are also known. For example, asymmetry can be measured by comparing opposite parts of the diffraction spectrum (for example, comparing the −1st and +1^{st} orders in the diffraction spectrum of a periodic grating). This can be done as described above and as described, for example, in U.S. patent application publication US 2006/0066855, which is incorporated herein in its entirety by reference. Another application of diffraction-based metrology is in the measurement of feature width (CD) within a target.

Thus, in a device fabrication process (e.g., a patterning process, a lithography process, etc.), a substrate or other objects may be subjected to various types of measurement during or after the process. The measurement may determine whether a particular substrate is defective, may establish adjustments to the process and apparatuses used in the process (e.g., aligning two layers on the substrate or aligning the reticle to the substrate), may measure the performance of the process and the apparatuses, or may be for other purposes. Examples of measurement include optical imaging (e.g., optical microscope), non-imaging optical measurement (e.g., measurement based on diffraction such as the ASML YieldStar metrology tool, the ASML SMASH metrology system), mechanical measurement (e.g., profiling using a stylus, atomic force microscopy (AFM)), and/or non-optical imaging (e.g., scanning electron microscopy (SEM)). The SMASH (SMart Alignment Sensor Hybrid) system, as described in U.S. Pat. No. 6,961,116, which is incorporated by reference herein in its entirety, employs a self-referencing interferometer that produces two overlapping and relatively rotated images of an alignment marker, detects intensities in a pupil plane where Fourier transforms of the images are caused to interfere, and extracts the positional information from the phase difference between diffraction orders of the two images which manifests as intensity variations in the interfered orders.

Metrology results may be provided directly or indirectly to the supervisory control system SCS. If an error is detected, an adjustment may be made to exposure of a subsequent substrate (especially if the inspection can be done soon and fast enough that one or more other substrates of the batch are still to be exposed) and/or to subsequent exposure of the exposed substrate. Also, an already exposed substrate may be stripped and reworked to improve yield, or discarded, thereby avoiding performing further processing on a substrate known to be faulty. In a case where only some target portions of a substrate are faulty, further exposures may be performed only on those target portions which meet specifications.

Within a metrology system, a metrology apparatus is used to determine one or more properties of the substrate, and in particular, how one or more properties of different substrates vary, or different layers of the same substrate vary from layer to layer. As noted above, the metrology apparatus may be integrated into the lithographic apparatus LA or the lithocell LC or may be a stand-alone device.

To enable the metrology, one or more targets can be provided on the substrate. In an embodiment, the target is specially designed and may comprise a periodic structure. In an embodiment, the target is a part of a device pattern, e.g., a periodic structure of the device pattern. In an embodiment, the device pattern is a periodic structure of a memory device (e.g., a Bipolar Transistor (BPT), a Bit Line Contact (BLC), etc. structure).

In an embodiment, the target on a substrate may comprise one or more 1-D periodic structures (e.g., gratings), which are printed such that after development, the periodic structural features are formed of solid resist lines. In an embodiment, the target may comprise one or more 2-D periodic structures (e.g., gratings), which are printed such that after development, the one or more periodic structures are formed of solid resist pillars or vias in the resist. The bars, pillars, or vias may alternatively be etched into the substrate (e.g., into one or more layers on the substrate).

In an embodiment, one of the parameters of interest of a patterning process is overlay. Overlay can be measured using dark field scatterometry in which the zeroth order of diffraction (corresponding to a specular reflection) is blocked, and only higher orders processed. Examples of dark field metrology can be found in PCT patent application publication nos. WO 2009/078708 and WO 2009/106279, which are hereby incorporated in their entirety by reference. Further developments of the technique have been described in U.S. patent application publications US 2011/0027704, US 2011/0043791, and US 2012/0242970, which are hereby incorporated in their entirety by reference. Diffraction-based overlay using dark-field detection of the diffraction orders enables overlay measurements on smaller targets. These targets can be smaller than the illumination spot and may be surrounded by device product structures on a substrate. In an embodiment, multiple targets can be measured in one radiation capture.

As lithography nodes keep shrinking, more and more complicated wafer designs may be implemented. Various tools and/or techniques may be used by designers to ensure complex designs are accurately transferred to physical wafers. These tools and techniques may include mask optimization, source mask optimization (SMO), OPC, design for control, and/or other tools and/or techniques. For example, a source mask optimization process is described in U.S. Pat. No. 9,588,438 titled “Optimization Flows of Source, Mask and Projection Optics”, which is incorporated in its entirety by reference.

The present systems, and/or methods may be used as stand-alone tools and/or techniques, and/or or used in conjunction with semiconductor manufacturing processes, to enhance the accurate transfer of complex designs to physical wafers.

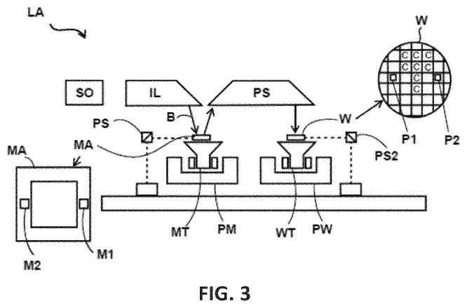

FIG. 3 schematically depicts an exemplary lithographic projection apparatus LA similar to and/or the same as the apparatus shown in FIG. 1 that can be used in conjunction with the techniques described herein. The apparatus comprises an illumination system IL configured to condition a beam B of radiation. In this example, the illumination system also comprises a radiation source SO. The apparatus comprises a first object table (e.g., reticle table) MT provided with a reticle holder to hold a reticle MA (e.g., a patterning device). It is connected to a first positioner to accurately position the reticle with respect to item PS. The apparatus comprises a second object table (substrate table) WT provided with a substrate holder to hold a substrate W (e.g., a resist-coated silicon wafer). It is connected to a second positioner to accurately position the substrate with respect to item PS. The apparatus comprises a projection system (“lens”) PS (e.g., a refractive, catoptric or catadioptric optical system) to image an irradiated portion of the reticle MA onto a target portion C (e.g., comprising one or more dies) of the substrate W.

As depicted, apparatus LA is of a transmissive type (i.e., has a transmissive reticle). However, in general, it may also be of a reflective type, for example (with a reflective reticle). The apparatus may employ a different kind of reticle to classic mask; examples include a programmable mirror array or LCD matrix.

The source SO (e.g., a mercury lamp or excimer laser, LPP (laser produced plasma) EUV source) produces a beam of radiation. This beam is fed into an illumination system (illuminator) IL, either directly or after having traversed conditioning means, such as a beam expander, for example. The illuminator IL may comprise adjusting means for setting the outer and/or inner radial extent (commonly referred to as o-outer and o-inner, respectively) of the intensity distribution in the beam. In addition, it will generally comprise various other components, such as an integrator and a condenser. In this way, the beam B impinging on the reticle MA has a desired uniformity and intensity distribution in its cross-section.

It should be noted with regard to FIG. 3 that the source SO may be within the housing of the lithographic projection apparatus (as is often the case when the source SO is a mercury lamp, for example), but that it may also be remote from the lithographic projection apparatus, the radiation beam that it produces being led into the apparatus (e.g., with the aid of suitable directing mirrors); this latter scenario is often the case when the source SO is an excimer laser (e.g., based on KrF, ArF or F₂ lasing).

The beam B subsequently intercepts the reticle MA, which is held on a reticle table MT. Having traversed the reticle MA, the beam B passes through the lens PL, which focuses the beam B onto a target portion C of the substrate W. With the aid of the second positioning means (and interferometric measuring means), the substrate table WT can be moved accurately, e.g., to position different target portions C in the path of the beam. Similarly, the first positioning means can be used to accurately position the reticle MA with respect to the path of the beam B, e.g., after mechanical retrieval of the reticle MA from a reticle library, or during a scan. In general, movement of the object tables MT, WT is realized with the aid of a long-stroke module (coarse positioning) and a short-stroke module (fine positioning), which are not explicitly depicted. However, in the case of a stepper (as opposed to a step-and-scan tool) the reticle table MT may just be connected to a short stroke actuator or may be fixed.

As described above, LA can be used in two different modes. In step mode, the reticle table MT is kept essentially stationary, and an entire reticle image is projected in one operation (i.e., a single “flash”) onto a target portion C. The substrate table WT is then shifted in the x and/or y directions so that a different target portion C can be irradiated by the beam. In scan mode, essentially the same scenario applies, except that a given target portion C is not exposed in a single “flash”. Instead, the reticle table MT is movable in a given direction (the so-called “scan direction”, e.g., the y direction) with a speed v, so that the projection beam B is caused to scan over a reticle image; concurrently, the substrate table WT is simultaneously moved in the same or opposite direction at a speed V=Mv, in which M is the magnification of the lens PL (typically, M=1/4 or 1/5). In this manner, a relatively large target portion C can be exposed, without having to compromise on resolution.

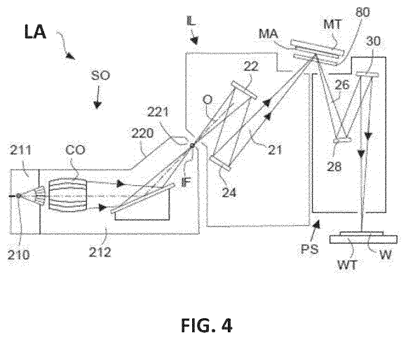

FIG. 4 shows the lithographic apparatus LA in more detail, including the source collector module SO, the illumination system IL, and the projection system PS. An EUV radiation emitting plasma 210 may be formed by a plasma source. EUV radiation may be produced by a gas or vapor, for example Xe gas, Li vapor or Sn vapor in which the radiation emitting plasma 210 is created to emit radiation in the EUV range of the electromagnetic spectrum. In an embodiment, a plasma of excited tin (Sn) is provided to produce EUV radiation.

The radiation emitted by the radiation emitting plasma 210 is passed from a source chamber 211 into a collector chamber 212. The collector chamber 212 may include a radiation collector CO. Radiation that traverses the radiation collector CO can be focused in a virtual source point IF. The virtual source point IF is commonly referred to as the intermediate focus, and the source collector module SO is arranged such that the virtual source point IF is located at or near an opening 221 in the enclosing structure 220. The virtual source point IF is an image of the radiation emitting plasma 210.

Subsequently the radiation traverses the illumination system IL, which may include a facetted field mirror device 22 and a facetted pupil mirror device 24 arranged to provide a desired angular distribution of the unpatterned beam 21, at the reticle MA, as well as a desired uniformity of radiation intensity at the reticle MA. Upon reflection of the unpatterned beam 21 at the reticle MA, held by the support structure MT, a patterned beam 26 is formed and the patterned beam 26 is imaged by the projection system PS via reflective elements 28, 30 onto a substrate W held by the substrate table WT.

More elements than shown may generally be present in the illumination system IL and the projection system PS. Further, there may be more mirrors present than those shown in the Figures, for example there may be 1-6 additional reflective elements present in the projection system PS than shown in FIG. 4. Alternatively, the source collector module SO may be part of an LPP radiation system.

As depicted in FIG. 3, in an embodiment the lithographic apparatus LA comprises an illumination system IL and a projection system PS. The illumination system IL is configured to emit a radiation beam B. The projection system PS is separated from the substrate table WT by an intervening space. The projection system PS is configured to project a pattern imparted to the radiation beam B onto the substrate W. The pattern is for EUV radiation of the radiation beam B.

The space intervening between the projection system PS and the substrate table WT can be at least partially evacuated. The intervening space may be delimited at the location of the projection system PS by a solid surface from which the employed radiation is directed toward the substrate table WT.

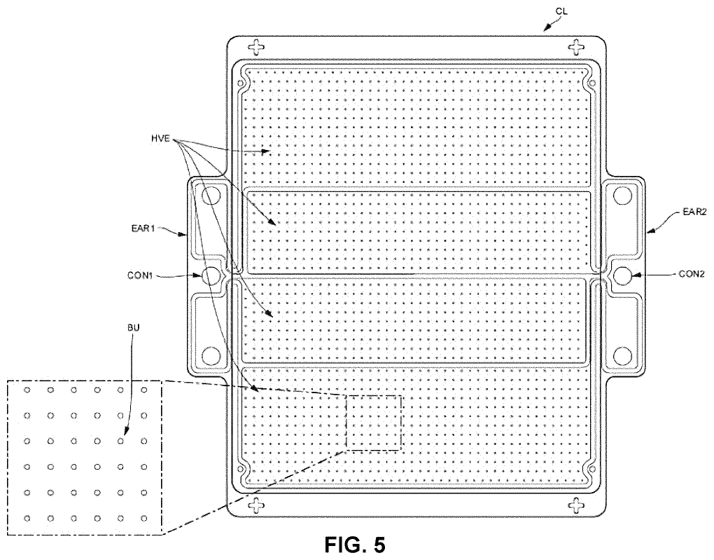

FIG. 5 schematically depicts a reticle clamp. The clamp is an electrostatic clamp. The reticle clamp CL has four high voltage electrodes HVE that are positioned vertically to each other and each stretch in the horizontal direction across the length of the clamp CL. The interior of the clamp CL contains a plurality of burls BU that project out from the surface of the clamp CL. The burls BU are arranged on a grid spanning the entire surface of the clamp CL. The burls BU are used to hold the reticle MA against the clamp CL. The burls BU use electrostatic charge to grip the reticle MA. Thereafter, the reticle MA can be released from the burls BU upon removal of the charge. The burls BU are used so that the reticle MA only contacts a small surface area of the clamp CL. This prevents contamination of the reticle MA. Further, the clamp CL has first and second ears EAR1 and EAR2 on each side. The first ear EAR1 comprises a first connection CON1 that can be used to drive a subset of burls BU to a particular voltage. The second ear EAR2 comprises a second connection CON2 used to drive another subset of burls BU to a particular voltage. The reason why only a subset of burls BU is used will be described in detail below.

As an example, in one embodiment there can be approximately 2000 burls BU on the clamp CL surface. However, in other embodiments, there can be anywhere between 500 burls and 5000 burls. Further, the burls BU are shown as circular in shape in FIG. 5. However, the burls BU can also be square-shaped, triangle-shaped, oval-shaped, or any shape that provides a strong contact to the reticle MA.

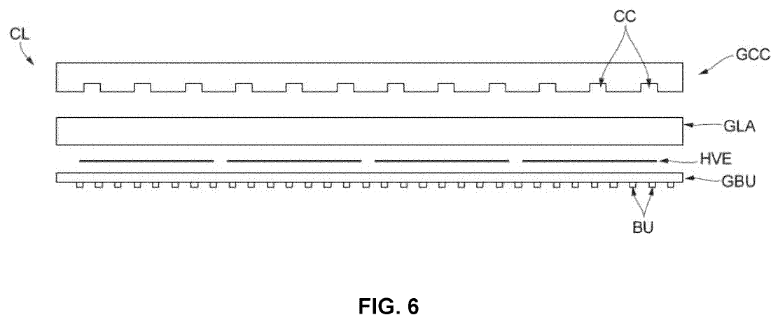

FIG. 6 schematically depicts a cross-sectional view of an exploded reticle clamp CL. The clamp CL includes a thin sheet of glass GBU, which is a dielectric body, with burls BU. Under the thin sheet of glass GBU are a plurality of thin high voltage electrodes HVE (four of such electrodes are illustrated in the depicted embodiment). Further underneath is a plate of glass GLA. The final layer is a plate of glass GCC with grooves. The grooves form closed cooling channels CC when the plate of glass GCC is mated against the plate of glass GLA to cool the clamp CL. Cold fluid is pumped through the cooling channels CC to cool the temperature of the reticle MA. All the glass and electrode layers are bonded or fused together to form the clamp CL.

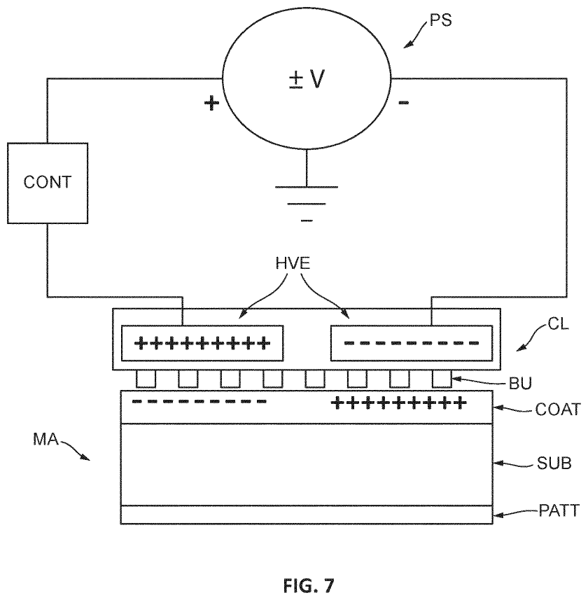

FIG. 7 schematically depicts a clamping function of the reticle clamp. A controller CONT controls the clamping function of the reticle clamp. The controller CONT may be comprised of a CPU, a microprocessor, a control unit, hardware, software, or any other control device to control the clamping function. The clamp CL is connected to a power supply PS. The power supply PS may be comprised of a wall outlet, batteries, fuel cells, or any other supply of power that is suitable for the clamp CL to use. When the switch is closed, as shown in FIG. 7, current runs through the circuit. The clamp CL has high voltage electrodes HVE, which become charged by the current. As a result, the left high voltage electrode HVE yields a positive charge, while the left high voltage electrode HVE becomes negatively charged. The reticle MA is composed of an imaging pattern PATT (that will be exposed on the substrate W) at its frontside, a reticle substrate SUB, and a conductive backside coating COAT. When the switch is closed, the reticle MA via the coating COAT is charged in such a way as to be attracted to the charged clamp CL. The left half of the coating COAT is negatively charged and is attracted to the positively charged left high voltage electrode HVE. The right half of the coating COAT is positively charged and is attracted to the negatively charged right high voltage electrode HVE. This attraction causes the reticle MA to be held by the clamp CL at the burls BU. Therefore, the charge from the high voltage electrodes HVE holds the reticle MA to the clamp CL.

On the other hand, when the switch is open, the clamp CL contains no charge, and the reticle MA is not attracted to the clamp CL. In one embodiment, the conductive backside coating COAT is made of chromium nitride (CrN) or tantalum boride (TaB). However, any conductive material that can be attracted or repelled from the high voltage electrodes HVE can be used. Additionally, the high voltage electrodes HVE apply a voltage of 3000 V to attract or otherwise clamp the reticle MA. The invention, however, is not limited to this, and in other non-limiting examples, the high voltage electrodes HVE can apply a voltage in the range of 1000 V to 5000 V. Furthermore, while two high voltage electrodes HVE are shown, the invention is not limited to this. For example, FIGS. 5, 6, 13, 14 each have four high voltage electrodes HVE. In various non-limiting examples, there are anywhere from two to eight high voltage electrodes HVE.

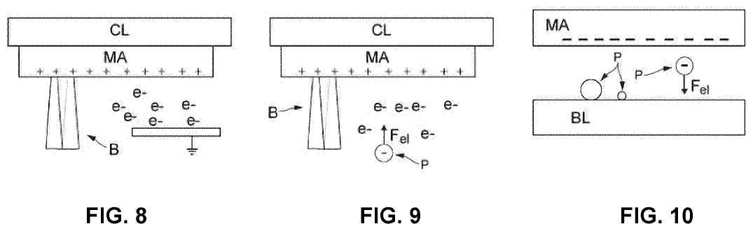

FIGS. 8-10 schematically depict a charged particle effect and biasing of the reticle. When the beam B (e.g., EUV lithography beam) is exposing the reticle MA, as shown in FIG. 8, secondary electrons (denoted by the symbol “e−”) are expelled from the surface of the reticle MA into the space below. This is due to the photoelectric effect on the plasma beam B. When used in exposure, the plasma beam B will emit many electrons. However, by biasing the reticle MA frontside with a positive charge, fewer electrons will be emitted into the reticle mini environment (RME). By maintaining a net positive potential on the reticle frontside, the number of electrons released during a pulse is reduced. The positively charged reticle MA will reduce the number of electrons that are released into the space.

FIG. 9 shows the effect of the beam exposure. Particles P in the space below the reticle MA, where the secondary electrons reside, can incur a predominantly negative charge. As a result, the particle P is attracted to the frontside of the positively charged reticle MA. Due to the charges being opposite, an electrostatic attractive force Fₑₗ acts on the particle P and pushes the particle P towards the reticle MA. Consequently, during beam exposure, particles P may stick to the frontside of the reticle MA. If this happens, when the reticle MA is exposed, the regions with the particles P would transfer inaccurate patterns to the substrate W, leading to higher defectivity.

FIG. 10 shows a reticle biasing method. Between beam exposure pulses, the front surface of the reticle MA is biased with a negative charge. As a result, the negatively charged particle P will be repelled away from the negatively charged surface of the reticle MA. The electrostatic attractive force Fₑₗ pushes the particle P towards reticle-masking (REMA) blades BL. The blades BL are used to block portions of the reticle MA that should not be exposed in the current pass. However, in this case, it can also function as a particle collector. By biasing the frontside of the reticle MA between beam pulses, particles P will be repelled away from the reticle MA, thus decreasing the defectivity.

The reticle MA frontside may be biased with positive charge when the plasma beam is on to reduce the number of electrons released from the plasma beam and repel contaminant particles. When the plasma beam is off, the reticle frontside is biased with negative charge to repel the electrons from the reticle MA. As the plasma beam pulse switches frequently from on to off and back to on, the reticle frontside bias is also changing constantly from positively charged to negatively charged and back to positively charged, respectively.

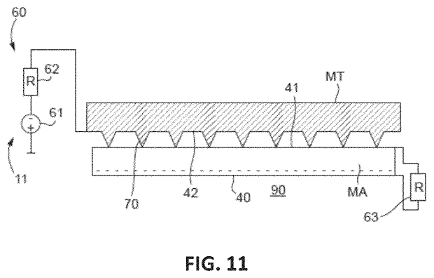

An electrostatic reticle clamp 11 is depicted in FIG. 11. The electrostatic reticle clamp 11 comprises a support structure MT having the elements of the clamp CL (see FIG. 6 for more details). A plurality of burls 70 (e.g., cone-shaped protrusions) on a support surface 42 of the support structure MT face a non-patterning backside surface 41 of the reticle MA. When the reticle MA is clamped to the support structure MT, the non-patterning surface 41 is in contact with distal ends of the plurality of burls 70. It is not necessary for each of the plurality of burls to be in contact with the non-patterning surface 41. In general, distal ends of one or more of the plurality of burls 70 may be in contact with the non-patterning surface 41 of the reticle MA. On the other hand, a patterning frontside surface 40 is on the other side of the reticle MA, and the exposure beam is incident on the patterning surface 40.

The non-patterning surface 41 is electrically connected to the voltage source 61 via the plurality of burls 70. The electrical connection between the voltage source 61 and the plurality of burls 70 may comprise the support surface 42 of the support structure MT being electrically connected to the voltage source 61, the plurality of burls 70 being electrically connected to the support surface 42 of the support structure MT, and the plurality of burls 70 being electrically connected to the non-patterning surface 41 of the reticle MA. It is not necessary for each of the plurality of burls to be electrically connected to the non-supporting surface 41. In general, one or more of the plurality of burls 70 may be electrically connected to the non-patterning surface 41.

Also, the patterning surface 40 and the non-patterning surface 41 are electrically connected. The electrical connection between the patterning surface 40 and the non-patterning surface 41 may be via a path integral to the reticle MA itself. Alternatively, the electrical connection between the patterning surface 40 and the non-patterning surface 41 may be via an external path, such as a wire, as is shown in FIG. 11.

Between the voltage source 61 and the plurality of burls 70, there may be at least one of a resistor 62, a diode, and a switch. The voltage source 61 and the resistor 62 are part of a voltage system 60 of the electrostatic reticle clamp 11. Additionally, or alternatively, there may be at least one of a resistor 63, a diode, and a switch between the non-patterning surface and the patterning surface. Further detail of these components is given below.

During each pulse of EUV radiation, a very large current may be drawn from the voltage source 61. The size of this current may be large enough to damage components such as the voltage source 61. Also, when very large currents are provided to the reticle MA, the reticle MA may heat up. This can cause the reticle MA to deform, which can cause errors in the pattern projected from the reticle MA onto the substrate W. To mitigate this, the patterning surface 40 may be connected to the voltage source 61 via at least one of a resistor 62, 63, diode, or switch.

In the case that a resistor 62, 63 is provided in the path between the voltage source 61 and the patterning surface 40, the size of the current drawn from the voltage source 61 during pulses of EUV radiation is limited by the additional resistance within the circuit. The resistance of the resistor 62, 63 (or the effective resistance of a combination of the resistors) may be greater than 1 kΩ, preferably greater than 10 kΩ. Desirably the resistance is less than 100 kΩ. In this way an RC characteristic of about 1 μs for the circuit can be achieved. It is desirable that the RC characteristic is less than about 10 μs.

Alternatively, a switch may be provided between the voltage source 61 and the patterning surface 40. The electrostatic reticle clamp 11 may be configured such that the switch is open whilst a pulse of EUV radiation is generated, and the switch is closed when a pulse of EUV radiation is not generated. That is, the bias voltage may be provided to the patterning surface 40 when the EUV pulse is off, but the bias voltage may not be provided to the patterning surface 40 when the EUV pulse is on. In this way, no current can be drawn by the reticle MA when a pulse of EUV radiation is generated, which means that surges of current from the voltage source 61 to the patterning surface 40 when the EUV pulse is generated are prevented.

To be able to provide this function, the switch may be capable of operating at the same frequency as the frequency of the EUV pulse. For example, the switch may be capable of operating at a frequency that is greater than 49 kHz, preferably greater than 59 kHz, and further preferably greater than 99 kHz. For example, the switch may be capable of operating at 100 kHz. The switch may be configured such that it is controlled by a signal from another component within the lithographic apparatus LA corresponding to the EUV pulse being turned on and off. That is, the controlling of the switch to be open or closed may be synchronized with the switching on and off of the pulse of EUV radiation.

This describes a scenario in which the bias voltage is cycled between negative and positive. If a positive bias voltage is provided to the patterning surface 40 whilst the pulse of EUV radiation is on, the number of photo electrons released from the patterning surface 40 is lower. The bias on the patterning surface 40 is switched to negative immediately after the pulse of EUV radiation has been switched off Therefore, a voltage biasing system in which the bias voltage is positive is provided to the patterning surface 40 whilst the pulse of EUV radiation is on would still have the effect that there is an overall reduction in the amount of photo electrons released for a given EUV pulse.

The embodiment described above have referred to the application of a negative bias voltage to the patterning surface 40, so that negatively charged contaminant particles are repelled from the patterning surface 40. However, there may be circumstances which cause contaminant particles within the reticle environment to become positively charged. In this case, a positive bias voltage may be applied to the patterning surface 40, such that the positively charged contaminant particles are repelled by the positively charged patterning surface 40.

To further reduce the number of contaminant particles attracted to the patterning surface 40 during EUV lithography, the pressure within the reticle environment could be further increased. When the pressure is increased, it is more likely that contaminant particles P generated within the reticle environment will be extracted. Consequently, less of the contaminant particles become negatively charged, so the problem of negatively charged particles being attracted to the patterning surface 40 when the patterning surface 40 becomes positively charged during the pulse of EUV radiation is mitigated.

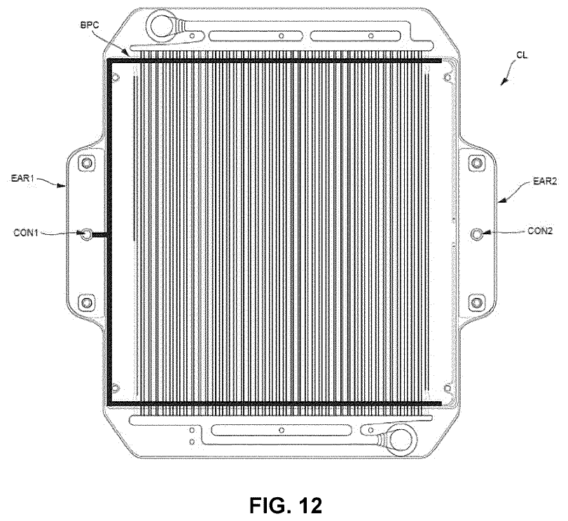

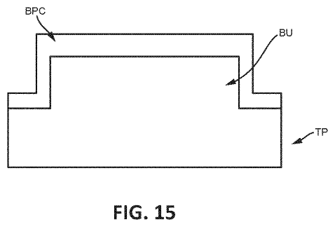

FIG. 12 schematically depicts an embodiment to achieve reticle frontside potential. The clamp CL includes first and second ear sections EAR1 and EAR2 that have first and second connections CON1 and CON2, respectively, for controlling the reticle potential. Previously, both connections CON1 and CON2 were grounded. However, in this case, one of the grounded pins can be re-purposed to function as a reticle frontside potential. As a result, the first connection CON1 is used for driving the reticle frontside potential (either positive or negative depending on the exposure sequence), while the second connection CON2 is used as a ground connection. The first connection CON1 is connected to a burl potential coating BPC, or a conductive coating, that can be routed to a subset of burls (see FIG. 15). When the subset of burls is covered with the burl potential coating BPC, each of the burls in the subset of burls ceases to provide a clamping function. The coating BPC covering the burls deactivates the clamping effect of those burls. On the other hand, the subset of burls now is driven to a slight potential by the burl potential coating BPC to provide reticle biasing, as described in FIGS. 8-10.

The subset of burls can for example be in the range of approximately 20 burls, as a non-limiting example, that can be provided with the burl potential coating BPC. Thus, of the approximately 2000 burls (as one example), only 20 burls (as one example) can be used for reticle frontside potential control. As a result, these burls can be driven to a slightly negative voltage. These burls are connected together through the conductive reticle backside coating. By driving the burls to a negative voltage, the frontside 40 of the reticle MA can have a negative potential. Therefore, the frontside 40 of the reticle MA can act as a particle repel mechanism and reduce reticle frontside 40 defectivity. Additionally, the burls can also be driven to a positive potential.

As only 20 burls of the 2000 burls are connected to the burl potential coating BPC in the above example, it should be apparent that a relatively small number (or subset) of burls need be used to emit the reticle frontside potential. Most of the burls (in this example, 1980 burls) are still used for clamping the reticle MA. The conductive coated burls no longer are used for clamping; rather, they are used only for reticle biasing. Although 20 burls cease to provide the clamping function, this does not affect clamping of the reticle MA. The remaining 1980 burls will still have plenty of clamping capability to hold the reticle MA without any performance impact. By using a subset of 20 burls for reticle frontside potential control and the remaining 1980 burls for clamping, the clamp CL can perform both voltage biasing and clamping at the same time. In other words, the clamp CL can reduce the number of particles that attach to the reticle MA while it holds the reticle MA.

In the example above, using only 20 burls as the subset of burls is sufficient to provide adequate reticle biasing to reduce the number of particles that stick to the reticle MA. Using significantly more burls may allow for greater reticle biasing but would negatively affect the clamping ability of the clamp CL. If all the burls were used for reticle biasing, then the reticle MA would be unable to be attached to the clamp CL. As a result, there is a trade-off between providing clamping and providing reticle biasing. It has been found that for a clamp CL having 2000 burls, re-purposing 20 burls for reticle biasing is optimal. In other embodiments, there can be as little as 6 burls and as many as 100 burls to be used in reticle biasing.

The burl potential coating BPC is conductive and transmits the potential at the connection to the connected burl. If a slightly positive voltage is set at the connection, then the connected burl will also be set at this slightly positive voltage due to the connection of the burl potential coating BPC. The burl potential coating BPC can be made of a material that is chrome (Cr) or titanium nitride (TiN).

Further, the slightly negative voltage can be between 5-10 V but is not limited to this range. The slightly positive voltage can range from 20 V all the way down to any voltage that is greater than 0 V. Additionally, there is no interference between the clamping of the high voltage electrodes HVE (at 3000 V) and the slight voltage of the burl potential coating BPC (at 5-10 V). The slight voltage is so small that it will not affect the clamping of the reticle MA.

Additionally, connection from the backside 41 to the frontside 40 of the reticle has to be managed via a reticle design change itself, such as a conductive coating connecting from reticle backside 41 to frontside 40. With this modification the frontside 40 of the reticle can be controlled to a calibrated potential (either positive or negative depending on the exposure sequence), thus acting as a way to prevent particles from depositing on the reticle FS thereby reducing the reticle frontside 40 defectivity.

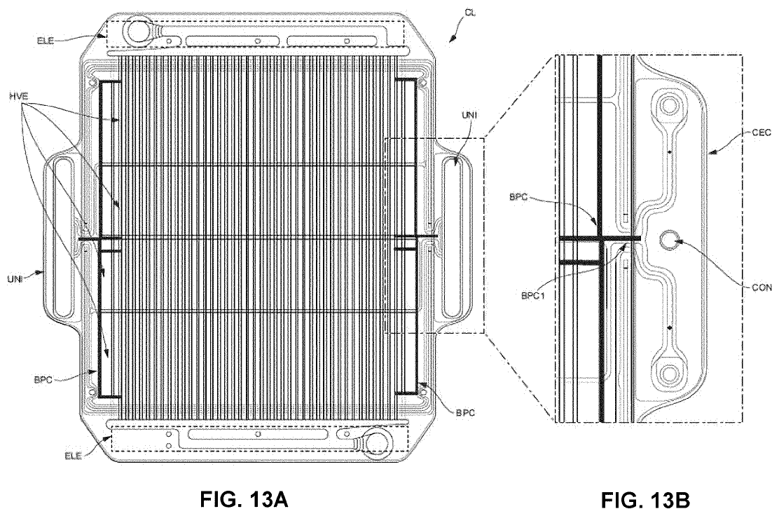

FIGS. 13A-13B schematically depict an embodiment to enable burl potential control. FIG. 13A shows the clamp CL having a plurality of electrodes HVE and ELE. The high voltage electrodes HVE, similar to those described in FIG. 7, are positioned vertically to each other and each stretch in the horizontal direction. Each of the 4 high voltage electrodes HVE is used to clamp the reticle MA onto its respective section of the clamp CL using the burls BU.

Further, electrodes ELE are positioned around the high voltage electrodes HVE inside the clamp. The top electrode ELE is positioned above the top high voltage electrode HVE, and the bottom electrode ELE is positioned below the bottom voltage electrode HVE. The ears of the clamp have UNICAP surfaces UNI.

FIG. 13B is a detailed drawing of the ear of FIG. 13A underneath the UNICAP surface UNI. A clamp ear coating CEC is coated on the ear. A connection CON is shown in the middle of the ear. The connection CON is connected to burl potential coating BPC for passing the potential. The burl potential coating BPC is also shown in FIG. 13A. Burl potential coating BPC1 that connects the connection CON to the burl potential coating BPC crosses over a clamp dam that separates the ear and the burls. The clamp dam is a leaky seal.

In this embodiment, the connection CON is driven to a burl potential, which can be a slightly positive or slightly negative voltage or even ground. When this happens, the electrodes ELE, the clamp ear coating CEC, and the UNICAP surfaces UNI are also set to the burl potential. The few burls that are connected to the burl potential coating BPC are also set to the burl potential.

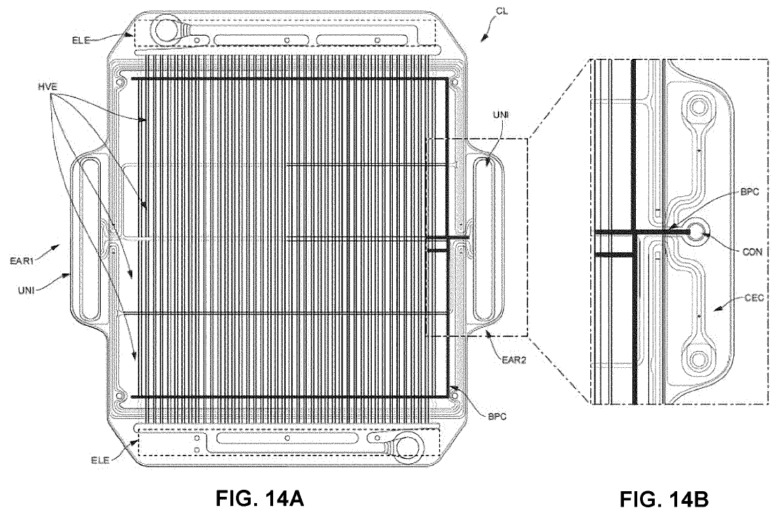

FIGS. 14A-14B schematically depict an embodiment to enable burl potential control and true ground. FIG. 14A is similar to FIG. 13A except for ear section EAR1 being connected to true ground. On the other hand, the ear section EAR2 is still connected to the burl potential. FIG. 14B shows the ear section EAR2 in more detail underneath the UNICAP surface UNI. In this embodiment, the burls with the burl potential coating BPC will be set to the burl potential. However, the electrodes ELE, the clamp ear coating CEC, and the UNICAP surfaces are all tied to ground.

By enabling burl potential control and true ground, there are several benefits. This embodiment has greater flexibility and control of the pins. Additionally, there is the ability to separate the burl potential from the ground. As a result, the burl and the ear can be controlled separately.

FIG. 15 schematically depicts an embodiment of the burl configuration. FIG. 15 shows a cross-section of a burl that is used for reticle frontside biasing. The burl BU is supported on a top plate TP. Coated on the burl BU is the burl potential coating BPC. The burl potential coating BPC may be a titanium nitride (TiN) coating that covers both the top surface and the side surface of the burl BU. The burl potential coating BPC biases the selective burls BU in order to provide reticle frontside biasing. A positive charge will be provided when the plasma beam is on, and a negative charge will be provided when the plasma beam is off. As a result, defectivity can be reduced.

The specification describes an electrostatic reticle clamp CL that can be seen in FIG. 6 that includes a dielectric body GBU, electrodes HVE that are configured to apply a charge to a first side of the dielectric body GBU facing the electrodes HVE for electrostatically clamping a reticle MA (see FIG. 7) on a second side of the dielectric body GBU where a plurality of burls BU project out, the plurality of burls BU on the second side of the dielectric body GBU and configured to contact the reticle MA, a conductive coating BPC shown in FIG. 15 that is disposed on a surface of a subset of the burls BU, a power source PS shown in FIG. 7, and a controller CONT configured to provide voltage from the power source PS to the conductive coating BPU.

The controller CONT and the power source PS of the electrostatic reticle clamp CL are configured to apply a positive voltage to the conductive coating BPC (see FIGS. 12-15). As a result, the positive voltage will apply a positive charge to a backside 41 of the reticle MA having the conductive backside coating COAT (shown in FIG. 7) and mounted on the burls BU for reducing the number of electrons (shown as e− in FIGS. 8-9) that are released into a reticle mini environment during an EUV pulse B. A positive voltage is applied when the EUV beam B is on in order to minimize the number of electrons released into the RME. This EUV beam B being on is shown in FIGS. 8-9. When the backside 41 of the reticle MA receives a positive charge, the charge will reach the frontside 40 of the reticle MA. As a result, the controller CONT and the power source PS of the electrostatic reticle clamp CL are configured to apply a positive voltage to the conductive coating BPC (see FIGS. 12-15) to apply a positive charge to a frontside 40 of the reticle MA having the imaging pattern PATT.

The controller CONT and the power source PS (FIG. 7) are configured to apply a negative voltage to the conductive coating BPC (FIGS. 12-15) to apply a negative charge to a backside 41 of a reticle MA having the conductive backside coating COAT (shown in FIG. 7) and mounted on the burls BU for repelling particles P from a frontside 40 of the reticle MA between EUV pulses. The negative voltage is applied when the EUV beam B is off to repel the negatively charged particles P from the frontside 40 of the reticle MA, also negatively charged. This embodiment is shown in FIG. 10. When the backside 41 of the reticle MA receives a negative charge, the charge will reach the frontside 40 of the reticle MA. As a result, the controller CONT and the power source PS of the electrostatic reticle clamp CL are configured to apply a negative voltage to the conductive coating BPC (see FIGS. 12-15) to apply a negative charge to a frontside 40 of the reticle MA having the imaging pattern PATT.

As shown in FIGS. 12-15, the conductive coating BPC, also called the burl potential coating, comprises a coating that is made of chrome (Cr). Alternatively, the conductive coating BPC can be made of a titanium nitride (TiN) material. Further, the reticle clamp CL comprises a plurality of high voltage and ground connections CON1 and CON2 on ear portions EAR1 and EAR2 of the clamp CL, as seen in FIG. 12, wherein the ear portions are coated with a conductive clamp ear coating CEC (seen in FIGS. 13B and 14B), and wherein the conductive coating CEC is connected to the ground pin on at least one of the clamp ear portions EAR1 and EAR2. One or more caps UNI (see FIGS. 13A and 14A) is positioned over the ear portions EAR1 and EAR2 (see FIGS. 12-14), and the one or more caps are electrically connected with the conductive clamp ear coating CEC.

The conductive coating BPC1 (shown in FIG. 13B) crosses over a raised structure separating the clamp ear portions EAR and the burls BU, and the raised structure comprises a leaky seal for connecting the burls. The raised structure isolates the clamp ear portion EAR from the burls BU portion. As shown in FIG. 12, the ground connection CON1 on one of the ears EAR1 is modified to provide voltage to the conductive coating BPC. Conductive coating BPC is connected to the connection CON1. As a result, any voltage provided to the connection CON1 will reach the conductive coating BPC. Moreover, the ground pin CON2 on the other ear EAR2 remains connected to ground. This setup also applies to FIGS. 14A-14B. At least one electrode HVE is connected to ground, as shown in FIGS. 8A, 13A, and 14A. The conductive coating BPC provides a conductive path from the power source PS (FIG. 7) to the surface on the subset of burls BU. The conductive path of the conductive coating BPC can be seen in FIGS. 12-14.

A method for forming an electrostatic clamp CL (FIG. 6) will now be described. First, a dielectric body GBU with a plurality of burls BU on a first side is provided. Second, a conductive coating BPC (FIG. 15) is applied to the first side of the dielectric body GBU. Third, the conductive coating BPC is patterned on the first side of the dielectric body GBU by retaining the coating BPC on a subset of the burls BU and a conductive path created by the conductive coating BPC enables a potential to be applied to the subset of burls BU through the conductive path (see FIGS. 12-14).

The patterning includes a lithographic patterning process to provide a conductive path created by the conductive coating BPC to the subset of burls BU from at least one clamp ear EAR at a peripheral portion of the clamp, seen in FIGS. 12-14. There is at least one glass body GLA on a second side of the dielectric body GBU, and two electrodes HVE between the dielectric body GBU and the at least one glass body GLA, as seen in FIG. 6.

The potential on the frontside of the reticle can be adjusted/controlled using a connection to the backside of the reticle, as disclosed in EP 22195470.4, hereby incorporated by reference.

Various embodiments of the present systems and methods are disclosed in the subsequent list of numbered clauses:
1. An electrostatic reticle clamp, comprising:
   a dielectric body;
   electrodes configured to apply a charge to a first side of the body for electrostatically clamping a reticle on a second side of the dielectric body;
   a plurality of burls on the second side of the dielectric body and configured to contact the reticle;
   a conductive coating disposed on a surface of a subset of the burls;
   a power source; and
      a controller configured to provide voltage from the power source to the conductive coating.
2. An electrostatic reticle clamp according to clause 1, wherein the controller and power source are configured to apply a positive voltage to the conductive coating to apply a positive charge to a backside of a reticle mounted on the burls for reducing the amount of electrons that are released into a reticle mini environment during an EUV pulse.
3. An electrostatic reticle clamp according to clause 2, wherein the controller and power source are configured to apply a positive voltage to the conductive coating to apply a positive charge to a frontside of the reticle.
4. An electrostatic reticle clamp according to any of the preceding clauses, wherein the controller and power source are configured to apply a negative voltage to the conductive coating to apply a negative charge to a backside of a reticle mounted on the burls for repelling particles from a frontside of the reticle between EUV pulses.
5. An electrostatic reticle clamp according to any of the preceding clauses, wherein the controller and power source are configured to apply a negative voltage to the conductive coating to apply a negative charge to a frontside of the reticle.
6. An electrostatic reticle clamp according to any of the preceding clauses, wherein the conductive coating comprises a chrome (Cr) or titanium nitride (TiN) coating.
7. An electrostatic reticle clamp according to clause 1, further comprising a plurality of high voltage and ground connections on ear portions of the clamp, wherein the ear portions are coated with a conductive clamp ear coating, and wherein the conductive clamp ear coating is connected to the ground pin on at least one of the clamp ear portions.
8. An electrostatic reticle clamp according to clause 7, further comprising one or more caps disposed over the ear portions, wherein the one or more caps are electrically connected with the conductive clamp ear coating.
9. An electrostatic reticle clamp according to any of the preceding clauses, wherein the conductive coating crosses over a raised structure separating the clamp ear portions and the burls, wherein the raised structure comprises a leaky seal for connecting the burls.
10. An electrostatic reticle clamp according to clause 7, wherein the ground connection on one of the ears is modified to provide voltage to the conductive coating, and wherein the ground pin on the other ear remains connected to ground.
11. An electrostatic reticle clamp according to any of the clause 10, wherein the at least one electrode is connected to ground.
12. An electrostatic reticle clamp according to any of the preceding clauses, wherein the conductive coating provides a conductive path from the power source to the surface on the subset of burls.
13. A method for forming an electrostatic reticle clamp, comprising:
   providing a dielectric body with a plurality of burls on a first side thereof;
   applying a conductive coating to the first side of the dielectric body; and
   patterning the conductive coating on the first side of the body by retaining the coating on a subset of the burls and a conductive path to enable a potential to be applied to the subset of burls through the conductive path.
14. The method of clause 13, wherein the patterning comprises a lithographic patterning process to provide a conductive path to the subset of burls from at least one clamp ear at a peripheral portion of the clamp.
15. A method according to clause 13, further providing at least one glass body on a second side of the dielectric body, and two electrodes between the dielectric body and the at least one glass body.

The concepts disclosed herein may be associated with any generic imaging system for imaging sub wavelength features and may be especially useful with emerging imaging technologies capable of producing increasingly shorter wavelengths. Emerging technologies already in use include EUV (extreme ultra violet), DUV lithography that is capable of producing a 193 nm wavelength with the use of an ArF laser, and even a 157 nm wavelength with the use of a Fluorine laser. Moreover, EUV lithography is capable of producing wavelengths within a range of 20-5 nm by using a synchrotron or by hitting a material (either solid or a plasma) with high energy electrons in order to produce photons within this range.

While the concepts disclosed herein may be used for wafer manufacturing on a substrate such as a silicon wafer, it shall be understood that the disclosed concepts may be used with any type of manufacturing system, e.g., those used for manufacturing on substrates other than silicon wafers. In addition, the combination and sub-combinations of disclosed elements may comprise separate embodiments. For example, the cleaning system, and the associated lithography apparatus may comprise separate embodiments, and/or these features may be used together in the same embodiment.

The descriptions above are intended to be illustrative, not limiting. Thus, it will be apparent to one skilled in the art that modifications may be made as described without departing from the scope of the claims set out below.

1. An electrostatic reticle clamp, comprising:
a dielectric body;
one or more electrodes configured to apply a charge to a first side of the body for electrostatically clamping a reticle on a second side of the dielectric body;
a plurality of burls on the second side of the dielectric body and configured to contact the reticle;
a conductive coating disposed on a surface of a subset of the burls; and
a controller configured to provide voltage from a power source to the conductive coating.

2. The clamp according to claim 1, wherein the controller is configured to apply a positive voltage to the conductive coating to apply a positive charge to a backside of a reticle, when mounted on the burls, for reducing the amount of electrons that are released into a reticle mini environment during an EUV pulse.

3. The clamp according to claim 2, wherein the controller is configured to apply a positive voltage to the conductive coating to apply a positive charge to a frontside of the reticle.

4. The clamp according to claim 1, wherein the controller is configured to apply a negative voltage to the conductive coating to apply a negative charge to a backside of a reticle, when mounted on the burls, for repelling particles from a frontside of the reticle between EUV pulses.

5. The clamp according to claim 1, wherein the controller is configured to apply a negative voltage to the conductive coating to apply a negative charge to a frontside of the reticle.

6. The clamp according to claim 1, wherein the conductive coating comprises a chrome (Cr) or titanium nitride (TiN) coating.

7. The clamp according to claim 1, further comprising a plurality of high voltage and ground connections on ear portions of the clamp, wherein the ear portions are coated with a conductive clamp ear coating, and wherein the conductive clamp ear coating is connected to the respective ground connection on at least one of the ear portions.

8. The clamp according to claim 7, further comprising one or more caps disposed over the ear portions, wherein the one or more caps are electrically connected with the conductive clamp ear coating.

9. The clamp according to claim 1, wherein the conductive coating crosses over a raised structure separating ear portions and the burls, wherein the raised structure comprises a leaky seal for connecting the burls.

10. The clamp according to claim 7, wherein the ground connection on one of the ear portions is modified to provide voltage to the conductive coating, and wherein the ground connection on another ear portion remains connected to ground.

11. The clamp according to claim 10, wherein the at least one electrode is connected to ground.

12. The clamp according to claim 1, wherein the conductive coating provides a conductive path from the power source to the surface on the subset of burls.

13. A method for forming an electrostatic reticle clamp, the method comprising:
applying a conductive coating to a first side of a dielectric body having a plurality of burls at the first side; and
patterning the conductive coating on the first side of the body by retaining the coating on a subset of the burls and a conductive path to enable a potential to be applied to the subset of burls through the conductive path.

14. The method according to claim 13, wherein the patterning comprises a lithographic patterning process to provide a conductive path to the subset of burls from at least one clamp ear at a peripheral portion of the clamp.

15. The method according to claim 13, further providing at least one glass body on a second side of the dielectric body, and two electrodes between the dielectric body and the at least one glass body.

16. The method according to claim 13, wherein the conductive coating comprises a chrome (Cr) or titanium nitride (TiN) coating.

17. The method according to claim 13, further comprising forming a plurality of high voltage and ground connections on ear portions of the clamp, wherein the ear portions are coated with a conductive clamp ear coating, and wherein the conductive clamp ear coating is connected to the respective ground connection on at least one of the ear portions.

18. The method according to claim 17, wherein the ground connection on one of the ear portions is configured to provide voltage to the conductive coating, and wherein a ground connection on another ear portion remains connected to ground.

19. The method according to claim 13, wherein the conductive coating crosses over a raised structure separating ear portions and the burls, wherein the raised structure comprises a leaky seal for connecting the burls.

20. The method according to claim 13, wherein the conductive coating provides a conductive path from a power source to the surface on the subset of burls.
